(19) United States
(12) Patent Application Publication
(10) Pub. No.: US 2002/0058401 A1
(43) Pub. Date: May 16, 2002

(54) Metal line of semiconductor device and method for fabricating the same

(75) Inventor: Chang Yong Kim, Chungcheongbuk-do (KR)

Correspondence Address: BIRCH STEWART KOLASCH & BIRCH, PO BOX 747, FALLS CHURCH, VA, 22040-0747, US

(73) Assignee: LG Semicon Co., Ltd.

(21) Appl. No.: 10/043,175

(22) Filed: Jan. 14, 2002

Related U.S. Application Data
(63) Continuation of application No. 09/132,508, filed on Aug. 11, 1998, now abandoned.

(30) Foreign Application Priority Data
Dec. 26, 1997 (KR) 74392/1997

(51) Int. Cl. H01L 21/28; H01L 21/44; H01L 21/4763

(52) U.S. Cl. 438/571; 438/574; 438/578; 438/582

(57) ABSTRACT

A metal line of a semiconductor device and method of fabricating the same are provided in which the metal line deterioration due to electromigration is minimized to improve its reliability. The method of fabricating the metal line includes forming a barrier layer on an interlevel insulating layer including a contact hole; forming a plug to fill the contact hole; sequentially forming a metal layer and first anti-reflective coating layer on the plug and barrier layer; coating a bilevel resist on the first anti-reflective coating layer; patterning the bilevel resist using a half tone mask to form grooves on the surface of the bilevel resist; etching the bilevel resist, first anti-reflective layer and metal layer to a predetermined depth until a portion of the first antireflective coating layer placed under the grooves of the bilevel resist is exposed; simultaneously etching the bilevel resist, first anti-reflective coating layer and metal layer to expose the interlevel insulating layer, thereby forming a metal line with uneven surface having grooves; and forming a second anti-reflective coating layer on both sides of the first antireflective coating layer, metal line and barrier layer.

### BACKGROUND OF THE INVENTION

1. Field of the Invention

The present invention relates to a semiconductor device and, more particularly, to a metal line of a semiconductor device and method for fabricating the same, in which the metal line deterioration due to electromigration is minimized to improve its reliability.

2. Discussion of Related Art

FIG. 1 is a cross-sectional view of a metal line of a conventional semiconductor device, and FIGS. 2a to 2e are cross-sectional views showing a method of fabricating the metal line of that conventional semiconductor device. Referring to FIG. 1, an interlevel insulating layer 2 having a contact hole which exposes a predetermined portion of a semiconductor substrate 1 is formed on the substrate, and a barrier metal layer 4 is formed on the inner wall of the contact hole and a predetermined portion of interlevel insulating layer 2. A tungsten plug 5a is filled in the contact hole as high as barrier metal layer 4, and a metal layer 6 and anti-reflective coating layer 7 are sequentially formed on barrier metal layer 4 and tungsten plug 5a in a predetermined metal line shape.

A method of fabricating the semiconductor device having the aforementioned metal line structure is explained below. Referring to FIG. 2a, an oxide layer or nitride layer is formed on semiconductor substrate 1 to form interlevel insulating layer 2. Photoresist is coated on the substrate and patterned through exposure and development, and interlevel insulating layer 2 is anisotropically-etched to form contact hole 3 using the patterned photoresist as a mask exposing a predetermined portion of semiconductor substrate 1. Referring to FIG. 2b, Ti or TiN is deposited on the overall surface of the substrate, including contact hole 3, to form barrier metal layer 4. Thereafter, heat treatment is carried out so as to harden barrier metal layer 4 and reduce its contact resistance. Tungsten 5 is deposited on barrier metal layer 4 to fill contact hole 3.

Referring to FIG. 2c, tungsten layer 5 is flattened through chemical mechanical polishing (CMP) or etchback to form tungsten plug Sa. Here, barrier metal layer 4 is not removed but left during the formation of tungsten plug Sa. Metal layer 6 is then formed of Al or Cu having lower resistance on barrier metal layer 4 and tungsten plug 5a. Referring to FIG. 2d, in order to reduce the reflectivity of the metal line during exposure process, an anti-reflective coating material having low reflectivity, such as TiN, is deposited on metal layer 6 to form anti-reflective coating layer 7. Photoresist 8 is then coated on anti-reflective coating layer 7 and patterned through exposure and development such that photoresist 8 remains on a predetermined portion of anti-reflective coating layer 7. Referring to FIG. 2e, anti-reflective coating layer 7, metal layer 6 and barrier metal layer 4 are sequentially and anisotropically-etched using the patterned photoresist as a mask, exposing interlevel insulating layer 2.

The above-described conventional semiconductor device metal line has the following problems. First, there are limitations in securing a heat transmission area for reducing the temperature of the metal line by emitting heat through thermal conduction, heat resulting from Joule-heating due to an increased current density from a decrease in the line width of the metal line. Furthermore, it is difficult to restrain electromigration on the sides of the metal line because the anti-reflective coating layer and barrier metal are formed only on the top and bottom of the metal layer.

### SUMMARY OF THE INVENTION

Accordingly, the present invention is directed to a metal line of a semiconductor device and method of fabricating the same that substantially obviates one or more of the problems experienced due to the above and other limitations and disadvantages of the related art.

An object of the present invention is to provide a metal line of a semiconductor device and method of fabricating the same in which heat generated due to Joule-heating is effectively dissipated, e.g., through conduction, to maintain low metal line temperature and to improve its reliability.

Another object of the present invention is to provide a metal line of a semiconductor device and method of fabricating the same in which a barrier metal layer is formed on the side of the metal layer to restrain electromigration, thereby improving the reliability of the metal line.

Additional features and advantages of the invention will be set forth in the description which follows, and in part will be apparent from the description, or may be learned by practice of the invention. The objectives and other advantages of the invention will be realized and attained by the structure particularly pointed out in the written description and claims hereof as well as the appended drawings.

To achieve these and other advantages and in accordance with the purpose of the present invention, as embodied and broadly described, the metal line of a semiconductor device includes: a semiconductor substrate; an interlevel insulating layer formed on the semiconductor substrate, the interlevel insulating layer having a contact hole; a barrier layer formed on the inner wall of the contact hole and a portion of the interlevel insulating layer, which is placed in close proximity to the contact hole; a plug formed on a portion of the barrier layer, which is placed in the contact hole; a metal line formed on the barrier layer and plug, the metal line having uneven surface with a plurality of grooves; a first anti-reflective coating layer formed on a portion of the metal line, which corresponds to a protrusion portion between the grooves; and a second anti-reflective coating layer formed on the sides of the barrier layer, metal line and first anti-reflective coating layer.

A method of fabricating a metal line of a semiconductor device, includes the steps of: forming an interlevel insulating layer having a contact hole which exposes a predetermined portion of a semiconductor substrate; forming a barrier layer on the interlevel insulating layer including the contact hole; forming a plug, to fill the contact hole; sequentially forming a metal layer and first anti-reflective coating layer on the plug and barrier layer; coating bilevel resist on the first anti-reflective coating layer; patterning the bilevel resist using a half tone mask, to form grooves on the surface of the bilevel resist; etching the bilevel resist, first anti-reflective layer and metal layer to a predetermined depth until a portion of the first anti-reflective coating layer, placed under the grooves of the bilevel resist, is exposed; simultaneously etching the bilevel resist, first antireflective coating layer and metal layer, to expose the interlevel insulating layer, forming a metal line with uneven surface having grooves; and forming a second anti-reflective coating layer on both sides of the first anti-reflective coating layer, metal line and barrier layer.

It is to be understood that both the foregoing general description and the following detailed description are exemplary and explanatory and are intended to provide further explanation of the invention as claimed.

### BRIEF DESCRIPTION OF THE ATTACHED DRAWINGS

The accompanying drawings, which are included to provide a further understanding of the invention and are incorporated in and constitute a part of this specification, illustrate embodiments of the invention and together with the description serve to explain the principles of the invention:

In the drawings:

FIG. 1 is a cross-sectional view of a metal line of a conventional semiconductor device;

FIGS. 2a to 2e are cross-sectional views showing a method of fabricating the metal line of the conventional semiconductor device;

FIG. 3 is a cross-sectional view of a metal line of a semiconductor device according to the present invention;

FIGS. 4a to 4h are cross-sectional views showing a method of fabricating a metal line of a semiconductor device according to the first embodiment of the present invention; and

FIGS. 5a to 5h are cross-sectional views showing a method of fabricating a metal line of a semiconductor device according to the second embodiment of the present invention.

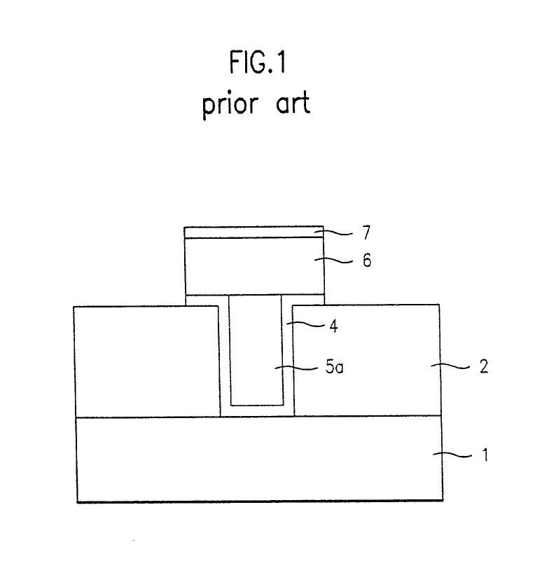

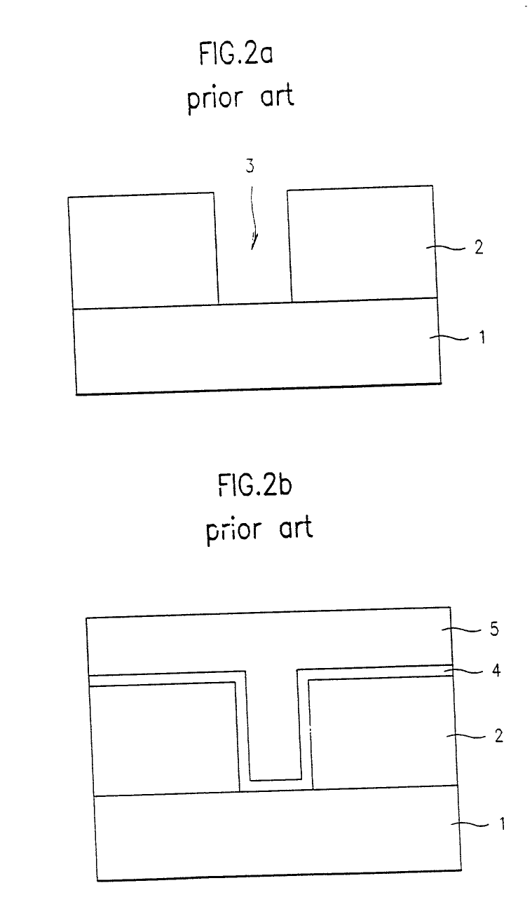

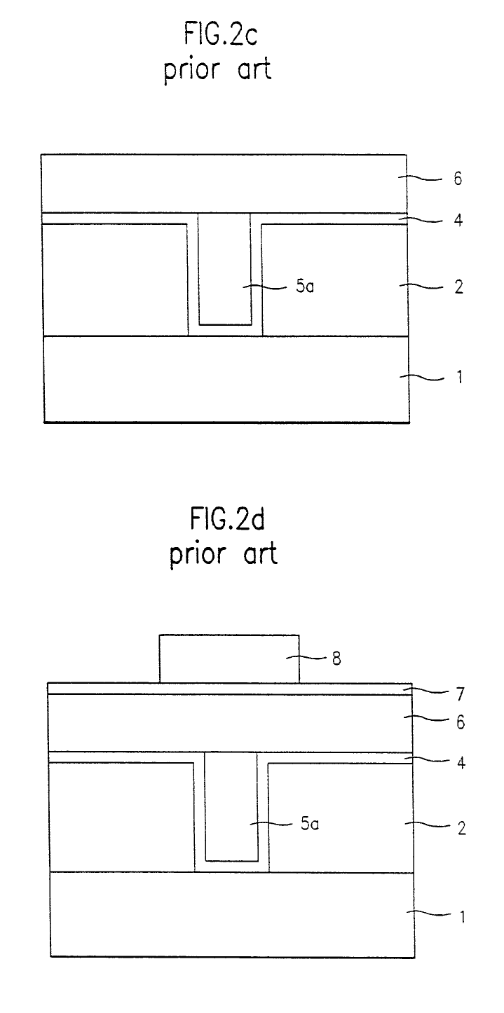

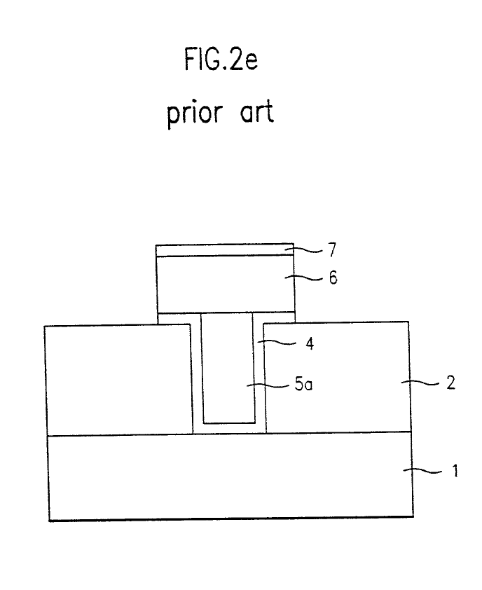

### DETAILED DESCRIPTION OF PREFERRED EMBODIMENT

Reference will now be made in detail to the preferred embodiments of the present invention, examples of which are illustrated in the accompanying drawings.

The present invention provides a metal line with uneven surface having multiple grooves, in contrast to the conventional flat metal line, so as to easily emit heat generated due to Joule-heating. Because heating of the line is an important parameter in the reliability of the metal line, the present invention is able to lengthen the life span of the metal line. More specifically, the life span of the metal line is determined by Black's equation:

t=A_{—}J⁻ⁿexp(Ea/KT),

where t is the life span of the metal line, A is the area of the metal line, J is current density, n is the acceleration factor, Ea is the actuation energy, K is the Boltzmanns constant (8.6×10⁻⁵ eV/°K) and T is the temperature of the metal line. As shown in Black's equation, the life of the metal line is proportional to the metal line area but inversely proportional to the metal line temperature. Accordingly, the metal line's heat emission area must be enlarged to effectively emit heat generated therefrom, thereby extending the life span of the metal line.

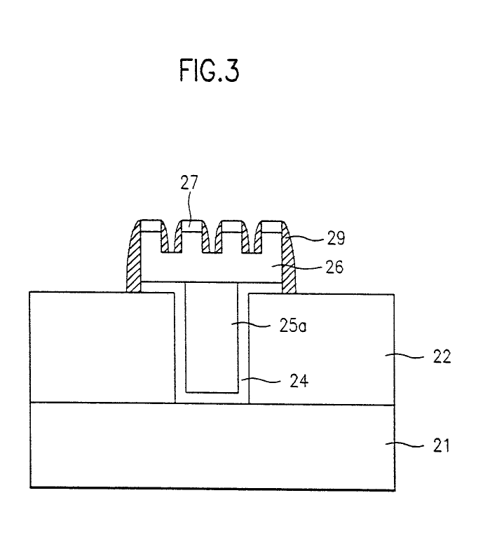

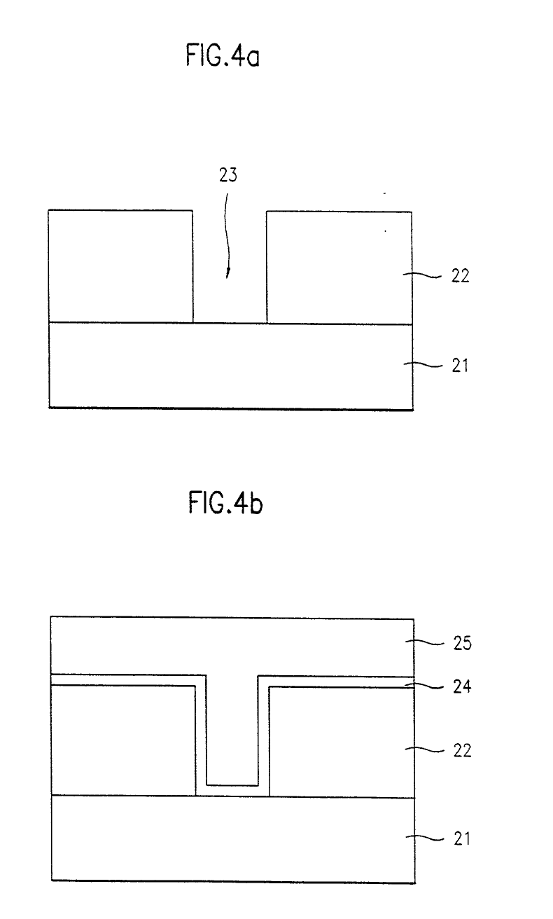

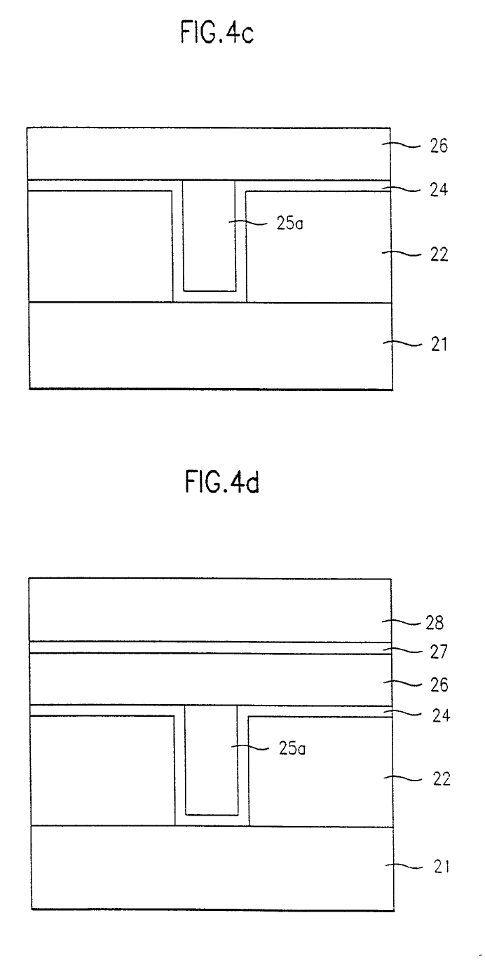

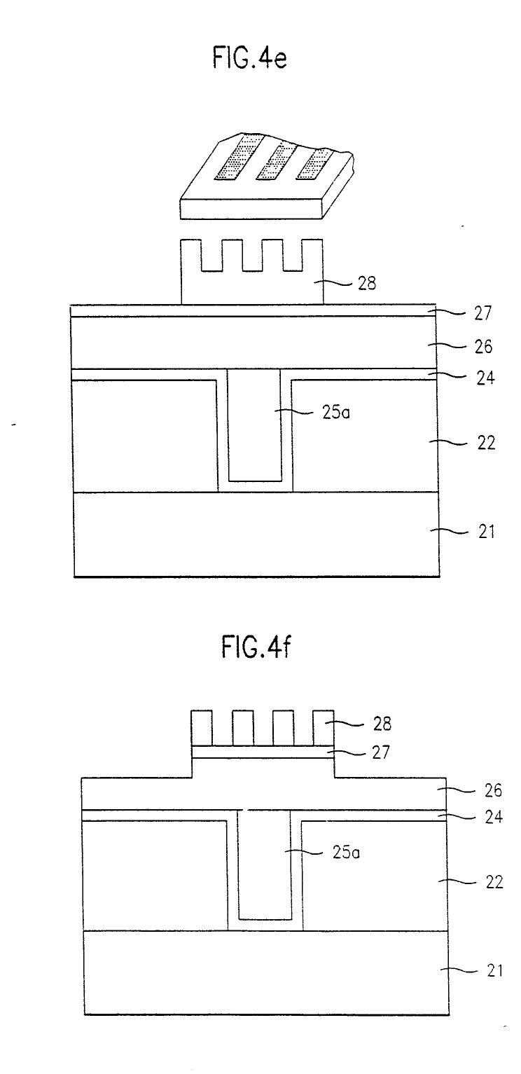

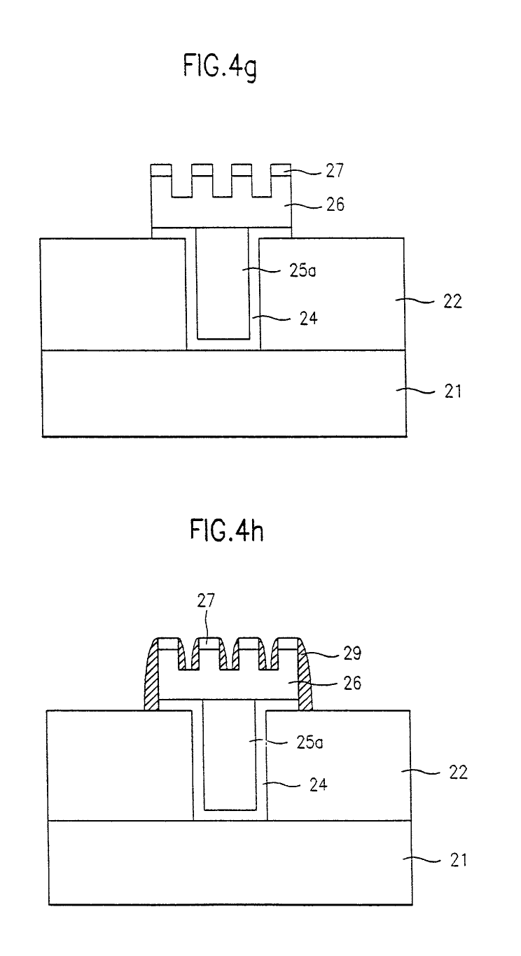

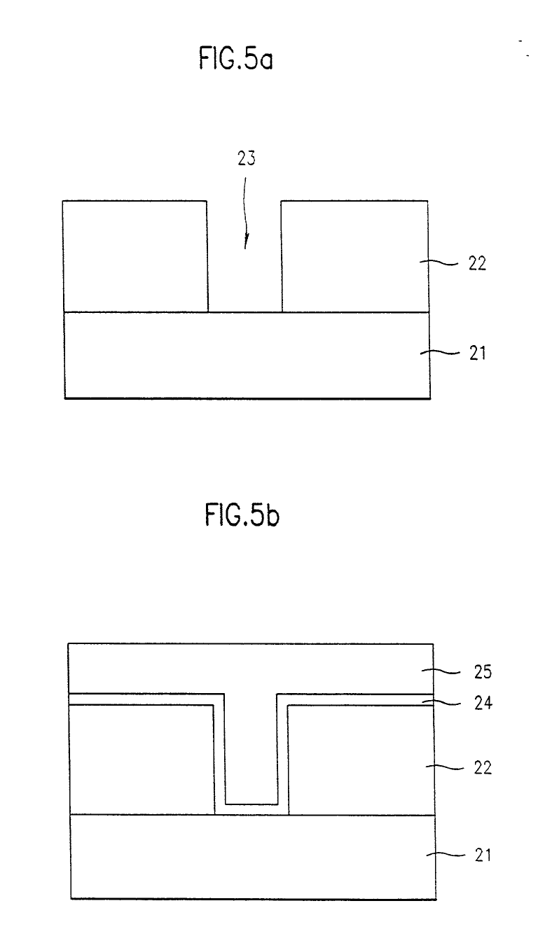

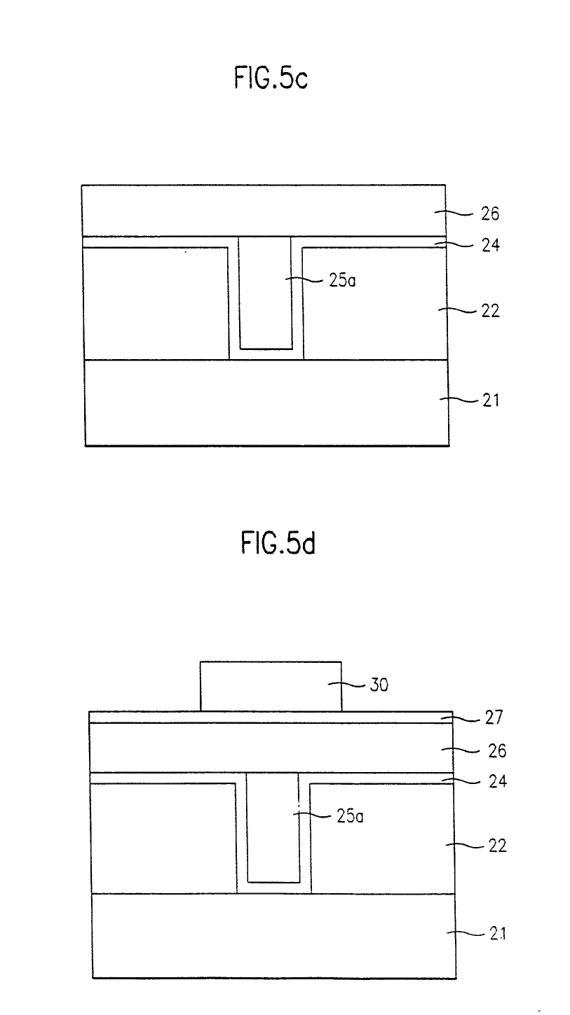

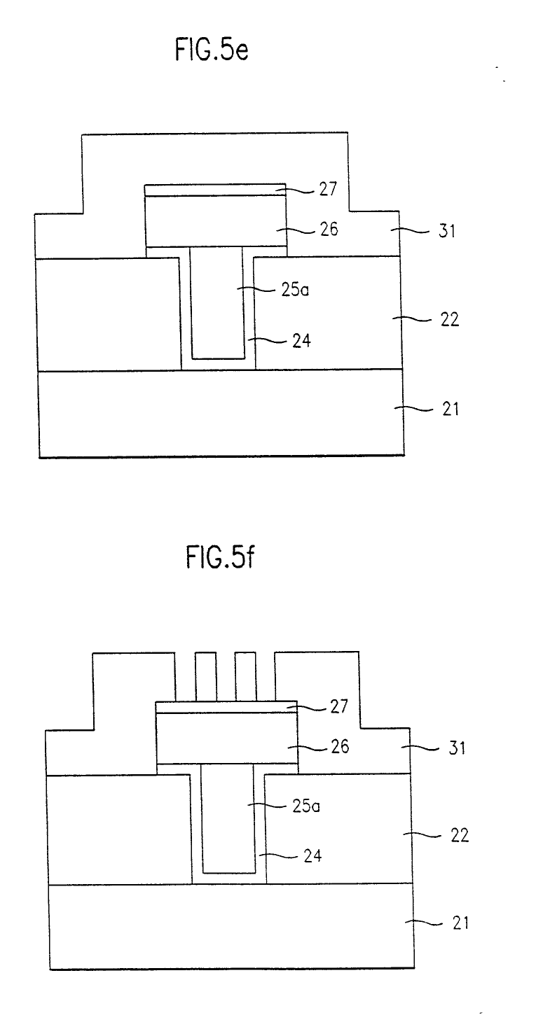

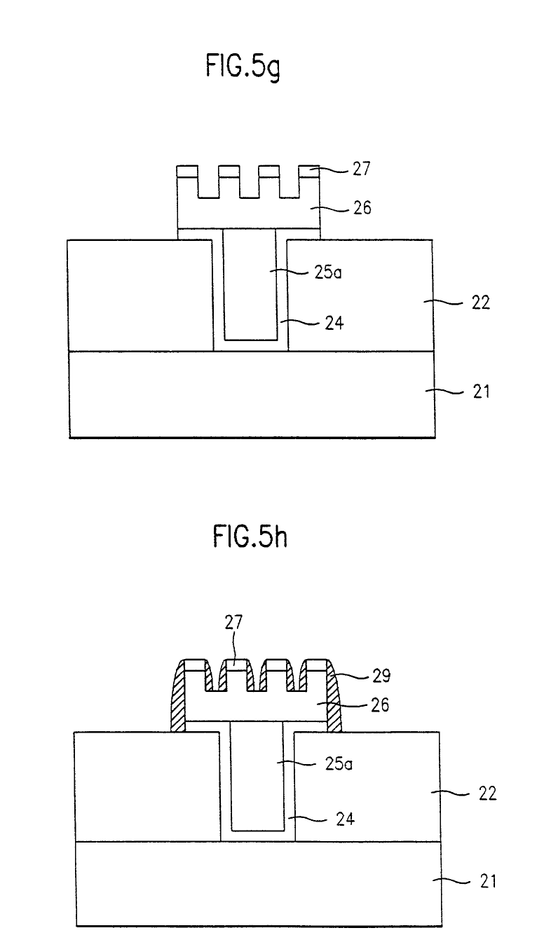

The metal line structure of a semiconductor device and method for fabricating the same according to the present invention are explained below with reference to the attached drawings. FIG. 3 is a cross-sectional view of a metal line of a semiconductor device according to the present invention, FIGS. 4a to 4h are cross-sectional views showing a method of fabricating a metal line of a semiconductor device according to the first embodiment of the present invention, and FIGS. 5a to 5h are cross-sectional views showing a method of fabricating a metal line of a semiconductor device according to the second embodiment of the present invention.

Referring to FIG. 3, an interlevel insulating layer 22 having a contact hole which exposes a predetermined portion of a semiconductor substrate 21 is formed on the substrate, and a barrier metal layer 24 is formed on the inner wall of the contact hole and a predetermined portion of interlevel insulating layer 22. A tungsten plug 25a is filled in the contact hole as high as barrier metal layer 24, and a metal layer 26 with an uneven surface having at least two grooves is formed on tungsten plug 25a and barrier metal layer 24. A first anti-reflective coating layer 27 is formed on metal layer 26 having uneven surface, and second anti-reflective coating layer 29 is formed on the both sides of barrier metal layer 24, metal layer 26 and first anti-reflective coating layer 27.

A method of fabricating a metal line of a semiconductor device according to the first embodiment of the invention is explained below. Referring to FIG. 4a, an oxide layer or nitride layer is formed on semiconductor substrate 21, to form interlevel insulating layer 22. A photoresist (not shown) is coated on the substrate and patterned through exposure and development, and interlevel insulating layer 22 is anisotropic-etched using the patterned photoresist as a mask, to form contact hole 23, exposing a predetermined portion of semiconductor substrate 21. Referring to FIG. 4b, Ti or TiN is deposited on the overall surface of the substrate, including contact hole 23, to form barrier metal layer 24. Thereafter, heat treatment is carried out so as to harden barrier metal layer 24 and reduce its contact resistance. Tungsten 25 is deposited on barrier metal layer 24, to fill contact hole 23.

Referring to FIG. 4c, the tungsten layer 25 is flattened through CMP or etchback, to form tungsten plug 25a. Here, barrier metal layer 24 is not removed but left during the formation of tungsten plug 25a. This is because that the barrier metal layer improves the crystallization and adhesion of the metal line so as to restrain electromigration, thereby increasing the reliability of the metal line. Al or Cu having lower resistance is deposited on barrier metal layer 24 and tungsten plug 25a to form metal layer 26. Referring to FIG. 4d, in order to reduce the reflectivity of the metal line during exposure process, an anti-reflective coating material having low reflectivity, such as TiN, is deposited on the metal layer 26 to form first anti-reflective coating layer 27, and then bilevel resist 28 is coated thereon by 50A or more.

Referring to FIG. 4e, in order to form a bilevel resist pattern having multiple grooves on its surface, bilevel resist 28 is exposed using a mask to partially expose portions where the multiple grooves will be formed and completely expose a portion of the resist which will be formed as the resist pattern. Then, the exposed resist is developed using a developer. Referring to FIG. 4f, bilevel resist pattern 28 with uneven surface having the grooves, first anti-reflective coating layer 27 and metal layer 26 are anisotropically-etched to expose a portion of first anti-reflective coating layer 27 placed under the grooves.

Referring to FIG. 4g, metal layer 26, barrier metal layer 24 and bilevel resist pattern 28 are anisotropically-etched, to expose interlevel insulating layer 22. By doing so, metal layer 26 has an uneven surface with multiple grooves, and first anti-reflective coating layer 27 is left only on the protrusion portions of metal layer 26. Referring to FIG. 4h, TiN is deposited on the overall surface of device thus formed. The TiN is then etched back to form second anti-reflective coating layer 29 on both sides of first anti-reflective coating layer 27, metal layer 26 and barrier metal layer 24, thereby restraining electromigration. Accordingly, the reliability of the metal line is improved.

A method of fabricating a metal line of a semiconductor device according to the second embodiment of the invention is explained below. Referring to FIG. 5a, an oxide layer or nitride layer is formed on semiconductor substrate 21 to form interlevel insulating layer 22. A photoresist (not shown) is coated on the substrate and patterned through exposure and development, and interlevel insulating layer 22 is anisotropic-etched using the patterned photoresist as a mask, to form contact hole 23, exposing a predetermined portion of semiconductor substrate 21. Referring to FIG. 5b, Ti or TiN is deposited on the overall surface of the substrate, including contact hole 23, to form barrier metal layer 24. Thereafter, heat treatment is carried out so as to harden barrier metal layer 24 and reduce its contact resistance. Tungsten 25 is deposited on barrier metal layer 24, to fill contact hole 23.

Referring to FIG. 5c, tungsten layer 25 is flattened through CMP or etchback, to form tungsten plug 25a. Here, barrier metal layer 24 is not removed but left during the formation of tungsten plug 25a. This is because that the barrier metal layer improves the crystallization and adhesion of the metal line so as to restrain electromigration, thereby increasing the reliability of the metal line. Al or Cu having lower resistance is deposited on barrier metal layer 24 and tungsten plug 5a to form metal layer 26. Referring to FIG. 5d, in order to reduce the reflectivity of metal line during exposure process, an anti-reflective coating material having low reflectivity, such as TiN, is deposited on metal layer 26 to form first anti-reflective coating layer 27, and then a first resist 30 is coated thereon. First resist 30 is patterned through exposure and development. It is left on a portion of the first anti-reflective coating layer 27 including tungsten plug 25a. Referring to FIG. 5e, first anti-reflective coating layer 27, metal layer 26 and barrier metal layer 24 are anisotropic-etched using the patterned first resist layer 30 as a mask. Thereafter, first resist layer 30 is removed, and a second resist 31 is coated on the overall surface of the substrate.

Referring to FIG. 5f, second resist 31 is selectively patterned through exposure and development processes to have a plurality of holes in a predetermined interval on the remaining first anti-reflective coating layer 27 and to be left on interlevel insulating layer 22. Referring to FIG. 5g, first anti-reflective coating layer 27 is anisotropic-etched and metal layer 26 is etched to a predetermined depth using the patterned second resist 31 as a mask, to form metal layer 26 with uneven surface having grooves. Then, second resist 31 is removed. Referring to FIG. 5h, TiN is deposited on the overall surface of semiconductor substrate 21 and etched back, to form second anti-reflective coating layer 29 on both sides of first anti-reflective coating layer 27, metal layer 26 and barrier metal layer 24. This restrains electromigration, improving the reliability of the metal line of the semiconductor device.

According to the present invention, heat generated due to Joule-heating is effectively emitted because the metal line has uneven surface with multiple grooves. Thus, the temperature of the metal line can be maintained low, improving its reliability.

By providing an uneven surface on the metal line, the life span of the metal line is also lengthened. Black's formula indicates that life span is proportional to surface area and inversely proportional to temperature. By providing an uneven surface, the surface area is increased (increased life span) and the temperature dissipation causes the temperature to fall (increased life span). Thus, the present invention increases the life span of the metal line.

Moreover, the anti-reflective layer and barrier metal layer are formed not only on the top and bottom of the metal layer but also on both sides of the metal layer. Accordingly, it is possible to restrain electromigration of the metal line of the semiconductor device.

It will be apparent to those skilled in the art that various modifications and variations can be made in metal line of a semiconductor device and method of fabricating the same of the present invention without departing from the spirit or scope of the invention. Thus, it is intended that the present invention cover the modifications and variations of this invention provided they come within the scope of the appended claims and their equivalents.

The foregoing description and the drawings are regarded as including a variety of individually inventive concepts, some of which may lie partially or wholly outside the scope of some or all of the following claims. The fact that the applicant has chosen at the time of filing of the present application to restrict the claimed scope of protection in accordance with the following claims is not to be taken as a disclaimer of alternative inventive concepts that are included in the contents of the application and could be defined by claims differing in scope from the following claims, which different claims may be adopted subsequently during prosecution, for example, for the purposes of a continuation or divisional application.

What is claimed is:

1. A method of fabricating a metal line of a semiconductor device, comprising:
sequentially forming a metal layer and first antireflective layer above and physically separated from a semiconductor substrate;
forming a resist above a portion of the first antireflective layer, at least one groove being defined in the resist that exposes a surface portion of the anti-reflective layer; and
simultaneously etching at least a portion of the first anti-reflective layer such that the upper surface of the metal layer is etched to a very shallow depth below the groove in the first anti-reflective layer to obtain a metal layer having an uneven top surface, the bulk of the metal layer remaining undisturbed and contiguous.

2. The method of claim 1, wherein the metal is formed of Al or Cu which has a low resistance.

3. The method of claim 1, wherein the resist is formed with at least two grooves.

4. The method of claim 1, further comprising:
forming a second anti-reflective layer on sides of the first anti-reflective layer and the metal line.

5. The method of claim 3, wherein the first and second anti-reflective layers are formed of TiN.

6. The method of claim 1, further comprising:
forming an interlevel insulating layer on a substrate;
forming a plug in a contact hole of the interlayer insulating layer; and
forming a barrier layer on a surface of the interlayer insulating layer and separating the plug from the interlayer insulating layer and the substrate,
where the metal layer is formed on surface regions of the plug and the barrier layer.

7. The method of claim 6, further comprising:
forming a second anti-reflective layer on sides of the first anti-reflective layer, the metal line and the barrier layer.

8. The method of claim 6, wherein the barrier layer is formed of at least one of Ti and TiN.

9. The method of claim 6, wherein the plug is formed of tungsten.

10. The method of claim 6, wherein the resist is a bilevel resist, further comprising:
etching the resist, the first anti-reflective layer and the metal layer until a portion of the first anti-reflective layer positioned under the groove is exposed.

11. The method of claim 10, further comprising:
patterning the resist using a mask to form the at least one groove in the resist.

12. The method of claim 11, wherein the resist is patterned such that portions positioned corresponding to the at least one groove are exposed for a longer period than portions positioned corresponding to protrusions between the at least one groove.

13. The method of claim 10, wherein the resist has a thickness of at least 50 angstroms.

14. The method of claim 6, wherein the simultaneous etching step includes simultaneously etching the resist, the first anti-reflective layer and the metal layer.

15. The method of claim 1, wherein the simultaneous etching of the first anti-reflective layer and the metal layer is performed using the resist as a mask.

16. The method of claim 15, further comprising:
removing the resist after the first anti-reflective layer and the metal layer are simultaneously etched.

17. The method of claim 16, further comprising:
forming a second anti-reflective layer on sides of the first anti-reflective layer and the metal line after the resist is removed.

18. A method of fabricating a metal line of a semiconductor device, comprising the steps of:
forming an interlevel insulating layer having a contact hole which exposes a predetermined portion of a semiconductor substrate;
forming a barrier layer on the interlevel insulating layer including the contact hole;
forming a plug as high as the barrier layer, to fill the contact hole;
sequentially forming a metal layer and first antireflective coating layer on the plug and barrier layer;
patterning the first anti-reflective coating layer, metal layer and barrier layer, coming into contact with the plug;
forming a resist layer on the first anti-reflective coating layer, the resist layer being patterned to have a plurality of holes in a predetermined interval;
sequentially etching the first anti-reflective coating layer and top surface of the metal layer to a shallow depth using the patterned resist layer as a mask such that the bulk of the metal layer remains undisturbed and contiguous, to form a metal line with uneven surface having a plurality of grooves;
removing the resist layer; and
forming a second anti-reflective coating layer on both sides of the first anti-reflective coating layer, metal line and barrier layer.
